(19) United States
(12) Patent Application Publication
(10) Pub. No.: US 2025/0085457 A1
(43) Pub. Date: Mar. 13, 2025

(54) SURFACE TREATMENT COMPOSITION FOR ORGANIC SUBSTRATE, OPTICAL ASSEMBLY, AND DISPLAY PANEL

(71) Applicant: Shenzhen China Star Optoelectronics Semiconductor Display Technology Co., Ltd., Shenzhen (CN)

(72) Inventors: Aibing BAO, Shenzhen (CN); Miao ZHOU, Shenzhen (CN); Lixuan CHEN, Shenzhen (CN)

(73) Assignee: Shenzhen China Star Optoelectronics Semiconductor Display Technology Co., Ltd., Shenzhen (CN)

(21) Appl. No.: 18/399,850

(22) Filed: Dec. 29, 2023

(30) Foreign Application Priority Data
Sep. 7, 2023 (CN) 202311155693.7

(51) Int. Cl. G02B 1/04; G02B 1/14; G02F 1/1339; H10K 59/80

(52) U.S. Cl. CPC G02B 1/04; G02B 1/14; G02F 1/1339; H10K 59/873

(57) ABSTRACT

Disclosed are a surface treatment composition for an organic substrate, an optical assembly, and a display panel. The surface treatment composition for the organic substrate includes a first solvent having a dipole moment greater than or equal to 10×10⁻³⁰ C·m, a second solvent having a dipole moment greater than 5×10⁻³⁰ and less than 10×10⁻³⁰ C·m and a boiling point of 50 to 150 degrees Celsius, and an acrylic monomer.

### CROSS-REFERENCE TO RELATED APPLICATIONS

The present disclosure claims priority to the Chinese Patent Application No. 202311155693.7, filed on Sep. 7, 2023, the contents of which are incorporated herein by reference in its entirety.

### TECHNICAL FIELD

The present disclosure relates to the field of high molecular materials, and more particularly, to a surface treatment composition for an organic substrate, an optical assembly, and a display panel.

### BACKGROUND

Organic polymer materials are widely used in electronic, chemical, mechanical, and other fields, such as automotive parts, display devices, and household appliances, due to their excellent physical and chemical properties.

In order to improve the hardness, corrosion resistance, wear resistance, weather resistance and other properties of the organic polymer material, or for the purpose of decoration and the like, a coating is usually disposed on a surface of the substrate made of the organic polymer materials. Therefore, the adhesion of the coating to the organic substrate directly affects the permanence of the coating and the durability of the organic substrate.

However, the molecular properties of the organic substrate and the coating components may result in a significant reduction in the adhesion between the coating and the organic substrate. For example, the molecular structure of polymethyl methacrylate (PMMA) has only ester groups with a relatively low polarity as an active group, and when the coating to be coated on the surface of the polymethyl methacrylate comprises a component having a high molecular functionality, the formation of the coating directly on the surface of the PMMA may produce large internal stress, resulting in poor adhesion between the coating and the PMMA.

### SUMMARY

In view of the above, the present disclosure provides a surface treatment composition for an organic substrate, a method of surface-treating an organic substrate, an optical assembly, and a display panel, which are capable of enhancing adhesion of a coating to the organic substrate.

Embodiments of the present disclosure provide a surface treatment composition for an organic substrate including:
a first solvent having a dipole moment greater than or equal to 10×10⁻³⁰ C·m;
a second solvent having a dipole moment greater than 5×10⁻³⁰ and less than 10×10⁻³⁰ C·m and a boiling point of 50 to 150 degrees Celsius; and
an acrylic monomer.

Embodiments of the present disclosure provide a method of surface-treating an organic substrate including the steps of:
applying a surface treatment composition for the organic substrate described in the above embodiments to a surface of an organic substrate;
drying the surface treatment composition for the organic substrate to form a rough surface with a specific surface morphology of the organic substrate.

Embodiments of the present disclosure provide an optical assembly including:
an organic substrate having a surface treated by a surface treatment composition for the organic substrate, wherein the surface has a root mean square surface roughness of 10 to 1,000 nm and a maximum height surface roughness of 20 to 2,000 nm.

Embodiments of the present disclosure further provide a display panel including:
a panel body, and
a optical assembly, the optical assembly being provided on a surface of the panel body,
wherein the optical assembly includes:
an organic substrate close to the panel body, the organic substrate has a surface treated by a surface treatment composition for an organic substrate, the surface is on a side of the organic substrate away from the panel body, and the surface has a root mean square surface roughness of 10 to 1,000 nm and a maximum height surface roughness of 20 to 2,000 nm.

### BRIEF DESCRIPTION OF THE DRAWINGS

FIG. 1 is an atomic force microscope (AFM) view of a surface of an organic substrate that is treated using a surface treatment composition for an organic substrate according to some embodiments of the present disclosure.

FIG. 2 is a flow chart of a method of surface-treating an organic substrate according to some embodiments of the present disclosure.

FIG. 3 is a schematic diagram of an optical assembly according to some embodiments of the present disclosure.

FIG. 4 is a schematic diagram of surface roughness of the surface-treated PMMA according to some embodiments of the present disclosure.

FIG. 5 is a schematic diagram of a display panel according to some embodiments of the present disclosure.

### DETAILED DESCRIPTION OF THE EMBODIMENTS

Embodiments of the present disclosure provide a surface treatment composition for an organic substrate, a method of surface-treating an organic substrate, an optical assembly, and a display panel. Various embodiments of the present disclosure are described in a form of ranges, which are only for convenience and brevity and should not be construed as a limitation on the scope of the present disclosure. Thus, the description of the ranges includes all possible sub-ranges as well as any single numerical value within those ranges. For example, the description of a range from 1 to 6 should be construed to specifically include sub-ranges, e.g., from 1 to 3, from 1 to 4, from 1 to 5, from 2 to 4, from 2 to 6, from 3 to 6, or the like, as well as any single number within the range, e.g., 1, 2, 3, 4, 5, or 6. Additionally, numerical ranges herein include any quoted numbers (fractions or integers) within the referred ranges.

An embodiment of the present disclosure provides a surface treatment composition for an organic substrate comprising:
a first solvent having a dipole moment greater than or equal to 10×10⁻³ Coulomb m (C·nm);
a second solvent having a dipole moment of 5×10⁻³⁰ to 10×10⁻³⁰ C·m and a boiling point of 50 to 150 degrees Celsius; and
an acrylic monomer.

Specifically, the first solvent and the acrylic monomer in the surface treatment composition for the organic substrate are utilized to erode a surface of the organic substrate to form a rough structure. The second solvent in the surface treatment composition for the organic substrate is utilized to regulate the morphology of the rough structure. On the one hand, the second solvent can balance the degree of erosion caused by the first solvent and the acrylic monomer on the surface of the organic substrate. On the other hand, the second solvent has a relatively low boiling point, which facilitates drying and rapid removal of the surface treatment composition for the organic substrate, thereby allowing the surface-treating process to be controlled. Thus, the surface treatment composition for the organic substrate provided in the present embodiments can be used for surface treatment of the organic substrate to form the rough surface. Specific examples of the organic substrate include, but not limited to, polyimide (PI), polyethylene terephthalate (PET), triacetyl cellulose (TAC), polycarbonate (PC), polymethyl methacrylate (PMMA), and other polymers.

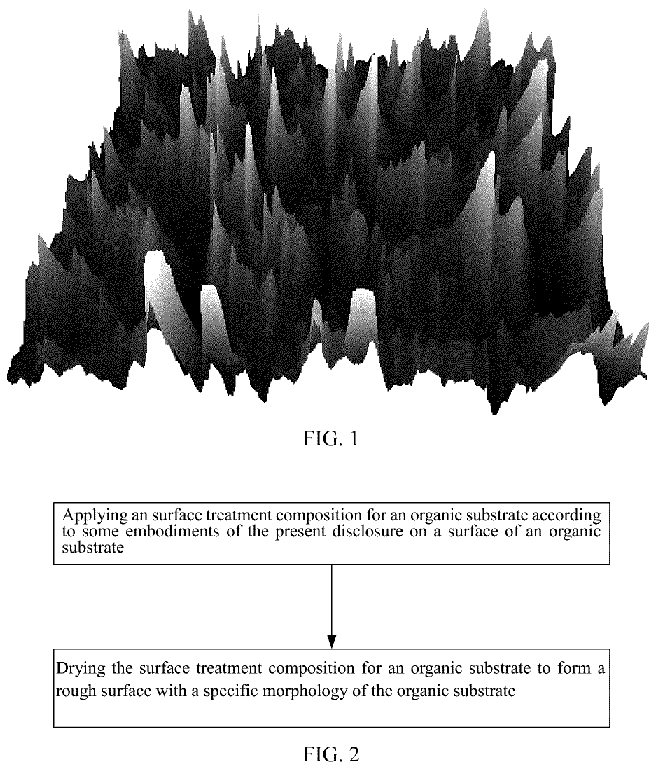

Referring to FIG. 1, the surface treatment composition for the organic substrate provided in the embodiments of the present disclosure enables the organic substrate to form a surface with a rough structure having a specific morphology, and thus an adhesion area of a subsequently formed coating is increased. Moreover, a concave-convex fitting is formed between the surface of the organic substrate and the subsequently formed coating, thereby enhancing adhesion of the coating to the organic substrate.

The first solvent includes one or more of formamide, methylformamide, N,N-dimethylformamide, N,N-diethylformamide, acetamide, methylacetamide, N,N-dimethylacetamide, N-methylpropionamide, 2-pyrrolidone, N-methylpyrrolidone, F-caprolactam, dimethylsulfoxide, dimethylsulfone, or sulfolane.

The second solvent includes one or more of methanol, ethanol, propanol, isopropanol, butanol, isobutanol, tert-butanol, pentanol, 2-methyl-1-butanol, isopentanol, sec-pentanol, tert-pentanol, tetrahydrofuran, tetrahydropyran, 2-methyltetrahydrofuran, ethylene glycol dimethyl ether, ethylene glycol diethyl ether, acetal, ethyl formate, propyl formate, butyl formate, isobutyl formate, amyl formate, isoamyl formate, methyl acetate, ethyl acetate, propyl acetate, butyl acetate, isobutyl acetate, sec-butyl acetate, tert-butyl acetate, amyl acetate, isoamyl acetate, methyl isoamyl acetate, methyl propionate, ethyl propionate, propyl propionate, butyl propionate, methyl butyrate, ethyl butyrate, propyl butyrate, isopropyl butyrate, methyl isobutyrate, ethyl isobutyrate, acetone, butanone, 2-pentanone, 3-pentanone, 3-methyl-2-butanone, 2-hexanone, 3-hexanone, 2-methyl-3-pentanone, 4-methyl-2-pentanone, 2,4-dimethyl-3-pentanone, cyclopentanone, or cyclohexanone.

The acrylic monomer includes one or more of acrylic acid, methyl acrylate, ethyl acrylate, butyl acrylate, isobutyl acrylate, methyl methacrylate, ethyl methacrylate, butyl methacrylate, isobutyl methacrylate, hydroxyethyl acrylate, tetrahydrofurfuryl acrylate, lauryl acrylate, isooctyl acrylate, or hydroxyl acrylate.

The surface treatment composition for the organic substrate includes 1 to 10 parts by weight of the first solvent, 65 to 94 parts by weight of the second solvent, and 5 to 25 parts by weight of the acrylic monomer. The term “parts by weight” indicates a mass of each component. The actual weight of “each part” is not specially defined, which may be 1 gram, 5 grams, 10 grams, 1 kilogram, 5 kilograms, 10 kilograms and so on, and may be adjusted according to the requirements of the actual scale of production, as long as the ratio between the components is determined. Specifically, a ratio of the mass of the first solvent:the mass of the second solvent:the mass of the acrylic monomer is (1-10):(65-94):(5-25). The above ratio may be based on the first solvent. The proportions of other various components may be freely adjusted within the listed range relative to the first solvent, and the adjustment of the proportions of one component does not affect the adjustment of the proportions of another component. Furthermore, the specific proportions of the components in the surface treatment composition for the organic substrate can be adjusted to regulate the specific morphology of the rough structure caused by erosion.

Referring to FIG. 2, an embodiment of the present disclosure provides a method of surface-treating an organic substrate, comprising the following steps.

S1: applying the surface treatment composition for the organic substrate described in the previous embodiments on a surface of the organic substrate.

The material of the organic substrate may be polymethyl methacrylate (PMMA), which may be provided on an outer side of a display panel to protect the display panel. Specifically, the surface treatment composition for the organic substrate may be coated on the surface of the organic substrate by a winding coating method. Specific examples of winding coating methods include, but not limited to, roll coating, gravure coating, reverse coating, brush coating, dip coating, spray coating, spin coating, pneumatic blade coating, mold coating, or the like.

S2: Drying the surface treatment composition for the organic substrate to form a rough surface with a specific morphology of the organic substrate.

Specifically, in terms of quick removal of the surface treatment composition for the organic substrate to precisely control the treatment time, a heat drying may be selected for drying.

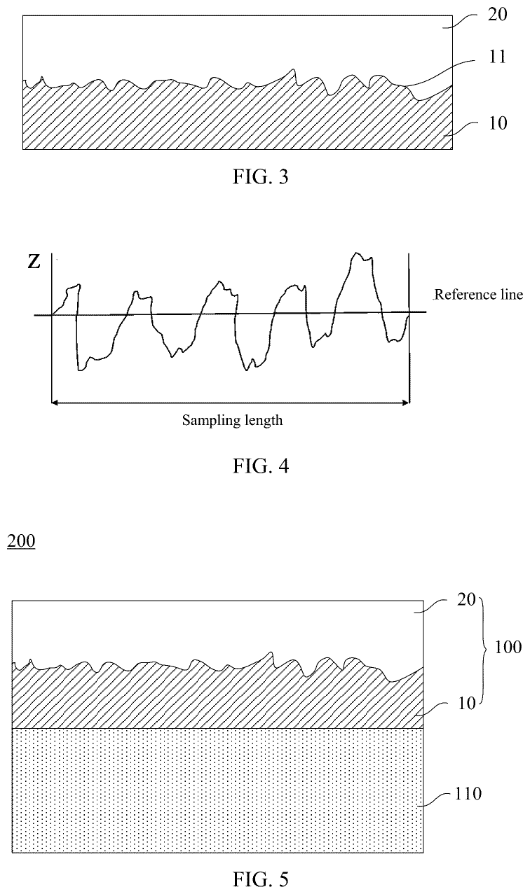

Referring to FIG. 3, an embodiment of the present disclosure provides an optical assembly 100. The optical assembly 100 includes an organic substrate 10 having a surface 11. Specifically, the surface 11 has a rough structure with a specific morphology. The surface 11 has a root mean square surface roughness Rq of 10 to 1,000 nm and a maximum height surface roughness Rz of 20 to 2,000 nm. The surface 11 is obtained by surface-treating the organic substrate using the method of surface-treating the organic substrate described in the above embodiments.

For a surface of an object treated by a machining method or other processing methods, peaks and valleys with small spacing may present on the micro profile thereof. The surface roughness is an indicator for representing microgeometric characteristics of the height and depth of these peaks and valleys and spacing. Referring to FIG. 4, the reference line is a profile centerline for evaluating roughness parameters. The reference line in the present disclosure is a profile arithmetic mean centerline, indicating that the areas of two portions of the profile above and below the centerline are equal to each other within the sampling length. The root mean square surface roughness Rq represents a root mean square value of peaks and valleys of the profile with respect to the ordinate Z of the reference line. The maximum height surface roughness Rz represents the sum of the maximum value of absolute values with regard to the ordinate Z of the reference line of the peaks of the profile and the maximum value of absolute values with regard to the ordinate Z of the reference line of the valleys of the profile. The lower the Rq and Rz, the lower the surface roughness of the object.

Specifically, the surface 11 has a root mean square surface roughness Rq of 10 to 1,000 nm and a maximum height surface roughness Rz of 20 to 2,000 nm, which can increase the contact area between the subsequently formed coating 20 and the surface 11, thereby increasing the adhesion of the coating 20 to the organic substrate 10. Moreover, the use of the surface roughness prevents the surface 11 from having an excessive surface roughness, because the excessive surface roughness may cause that the subsequently formed coating 20 fails to spread over the rough surface of the surface 11, leaving air between the surface 11 and the coating 20, and resulting in poor adhesion between the coating 20 and the organic substrate 10.

Still referring to FIG. 3, the coating 20 may be applied on the surface 11 of the optical assembly 100. The coating 20 may be a coating having a hardness to impart a hardness and wear resistance to the organic substrate 10. The coating 20 may have a thickness of 1 to 10 microns, specifically 2 to 8 microns, and more specifically 3 to 6 microns. The coating 20 may be formed on the surface 11 of the organic substrate 10 by a winding coating method. Specific examples of winding coating methods include, but not limited to, roll coating, gravure coating, reverse coating, brush coating, dip coating, spray coating, spin coating, pneumatic blade coating, mold coating, or the like.

According to the optical assembly 100 provided in the embodiments of the present disclosure, the organic substrate 10 is treated with the surface treatment composition for the organic substrate provided in the embodiments of the present disclosure to form the surface 11 having a rough structure with a specific morphology. Therefore, on the one hand, the contact area of the coating 20 is increased, and on the other hand, after the coating 20 is formed, a mechanical interlocking is formed by a concave-convex fitting between the surface 11 and the coating 20, thereby improving the adhesion of the coating 20 to the organic substrate 10. Further, the coating 20 is less prone to defects such as warping and cracking, and thus the durability of the optical assembly 100 can be improved.

The coating 20 comprises a polyurethane acrylate oligomer having a functionality greater than or equal to six. Specifically, a higher functionality can bring a higher photocuring activity and facilitate an increase in crosslink density. The coating 20 comprises a polyurethane acrylate oligomer having a functionality greater than or equal to six, which leads to formation of a compact crosslink structure of the coating 20 after photocuring, thereby improving the mechanical properties and increasing the hardness of the coating 20.

The coating 20 comprises a hexa-functional polyurethane acrylate oligomer having a structure as shown below:

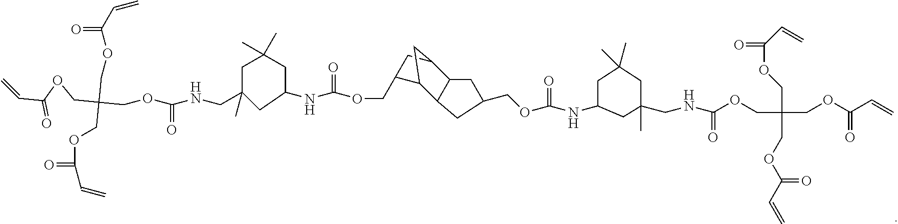 [SMILES: C=CC(=O)OCC(COC(=O)C=C)(COC(=O)C=C)COC(=O)NCC1(C)CC(NC(=O)OCC2CC3C4CC(COC(=O)NC5CC(C)(C)CC(C)(CNC(=O)OCC(COC(=O)C=C)(COC(=O)C=C)COC(=O)C=C)C5)C(C4)C3C2)CC(C)(C)C1]

The molecular structure of the hexa-functional polyurethane acrylate oligomer contains a plurality of carbocyclic structures, enhancing the rigidity of the molecular structure, enhancing the mechanical properties of the coating 20, and further improving the hardness of the coating 20.

The coating 20 further comprises an acrylate monomer having a functionality greater than or equal to three, which can dissolve and dilute the polyurethane acrylate oligomer having the functionality greater than or equal to six in the coating 20, adjust the viscosity of the components, and adjust the cure rate and crosslinking properties of the coating 20. Specific examples of acrylate monomers having the functionality greater than or equal to three include, but not limited to, one or more of trimethylolethane tri(meth)acrylate, trimethylolpropane tri(meth)acrylate, glycerol tri(meth)acrylate, pentaerythritol tri(meth)acrylate, di(trimethylolpropane) tri(meth)acrylate, dipentaerythritol tri(meth)acrylate, pentaerythritol tetra(meth)acrylate, di(trimethylolpropane) tetra(meth)acrylate, dipentaerythritol tetra(meth)acrylate, dipentaerythritol penta(meth)acrylate, di(trimethylolpropane) penta(meth)acrylate, dipentaerythritol hexa(meth)acrylate, or di(trimethylolpropane) hexa(meth)acrylate.

The coating 20 further comprises a photoinitiator. The photoinitiator may, under irradiation by a light source, absorb energy at a certain wavelength, and produce active intermediates with the ability to initiate polymerization, such as free radicals and cations, thereby triggering the polymerization and crosslinking reaction of prepolymers and monomer components, and finally achieving curing. In particular, the photoinitiator may include one or more of a type I photoinitiator or a type II photoinitiator. The type I (cleavage type) photoinitiator can generate free radicals by breaking down molecules due to differences in chemical structure or molecular binding energy. Specific examples of type I photoinitiators include, but not limited to, one or more of acetophenones such as 4-phenoxydichloroacetophenone, 4-tert-butyldichloroacetophenone, 4-tert-butyltrichloroacetophenone, diethoxyacetophenone, 2-hydroxy-2-methyl-1-phenylpropan-1-one, 1-(4-isopropylphenyl)-2-hydroxy-2-methylpropan-1-one, 1-(4-dodecylphenyl)-2-hydroxy-2-methylpropan-1-one, 4-(2-hydroxyethoxy)-phenyl(2-hydroxy-2-propyl) ketone, or 1-hydroxycyclohexylphenyl ketone; benzoins such as benzoin, benzoin methyl ether, benzoin ethyl ether, or benzyl dimethyl ketal; acylphosphine oxides or titanocene compounds. The type II (hydrogen-capturing) photoinitiator, after absorbing energy, is subjected to a bimolecular interaction with a co-initiator (i.e., a hydrogen donor, for example, tertiary amines) in the excited state to produce reactive free radicals. Specific examples of type II photoinitiators include, but not limited to, one or more of benzophenones such as benzophenone, benzoylbenzoic acid, benzoylbenzoic acid methyl ether, 4-phenylbenzophenone, hydroxybenzophenone, 4-benzoyl-4′-methyldiphenyl sulfide, or 3,3′-dimethyl-4-methoxybenzophenone; thioxanthones, such as thioxanthone, 2-chlorothioxanthone, 2-methylthioxanthone, 2,4-dimethylthioxanthone, isopropylthioxanthone, or the like.

The coating 20 comprises 60 to 100 parts by weight of the polyurethane acrylate oligomer having the functionality greater than or equal to six, 0 to 40 parts by weight of the acrylate monomer having the functionality greater than or equal to three, and 1 to 10 parts by weight of the photoinitiator. Specifically, the phrase “0 to 40 parts by weight of the acrylate monomer having a functionality greater than or equal to three” means that the acrylate monomer having the functionality greater than or equal to three may or may not be added. The term “parts by weight” indicates a mass of each component. The actual weight of each “part” is not specially defined, which may be 1 gram, 5 grams, 10 grams, 1 kilogram, 5 kilograms, 10 kilograms and so on, and may be adjusted according to the requirements of the actual scale of production, as long as the ratio between the components is determined. Specifically, a ratio of the mass of the polyurethane acrylate oligomer having the functionality greater than or equal to six: the mass of the acrylate monomer having the functionality greater than or equal to three: the mass of the photoinitiator is (60-100):(0-40):(1-10). The above ratio may be based on the polyurethane acrylate oligomer having the functionality greater than or equal to six. The proportions of other various components having the functionality greater than or equal to six may be freely adjusted within the listed range relative to the polyurethane acrylate oligomer, and the adjustment of the proportions of one component does not affect the adjustment of the proportions of another component.

For ease of coating, the coating 20 according to the present disclosure further includes another solvent. Specifically, the coating 20 may include 100 to 400 parts by weight of the solvent. That is, the mass of the polyurethane acrylate oligomer having the functionality greater than or equal to six: the mass of the solvent=(60-100):(100-400), based on the polyurethane acrylate oligomer having the functionality greater than or equal to six. The proportions of the solvent having the functionality greater than or equal to six may be freely adjusted as desired within the listed range based on the polyurethane acrylate oligomer. Specific examples of the solvent include, but not limited to, one or more of alcohols such as methanol, ethanol, isopropanol, esters such as ethyl acetate, propyl acetate, butyl acetate; ketones such as acetone, butanone, cyclohexanone, benzenes such as toluene, xylene, or the like. The solvent may have a boiling point of 50 to 150 degrees Celsius. When the boiling point of the solvent is lower than 50 degrees Celsius, the solvent has a high volatility, which may affect the thickness of the coating 20 formed by coating. When the boiling point of the solvent is higher than 150 degrees Celsius, the drying process of the solvent becomes difficult, which may affect the formation efficiency of the coating 20 and increase the process cost.

Referring to FIG. 5, an embodiment of the present disclosure provides a display panel 200 including the optical assembly 100 provided in the foregoing embodiments. Specifically, the display panel 200 includes the optical assembly 100 and a panel body 110, and the optical assembly 100 is disposed on a surface of the panel body 110. The organic substrate 10 of the optical assembly 100 is close to the panel body 110. The panel body 110 may be an organic light-emitting diode (OLED) display panel, a quantum dot light-emitting diode (QLED) display panel, a micro light-emitting diode (Micro-LED) display panel, a mini light-emitting diode (Mini-LED) display panel, or a liquid crystal display panel.

The optical assembly 100 is capable of protecting the panel body 110. Since the adhesion of the coating 20 to the organic substrate 10 in the optical assembly 100 is enhanced according to the foregoing embodiments, the coating 20 is less prone to defects such as warping and cracking. Therefore, the optical assembly 100 can better protect the entire surface of the display panel 200 and improve the durability of the display panel 200.

Hereinafter, the surface treatment composition for the organic substrate, the method of surface-treating an organic substrate, the optical assembly, and the display panel of the present disclosure will be described by specific examples.

### Synthesis of Hexa-Functional Polyurethane Acrylate Oligomer

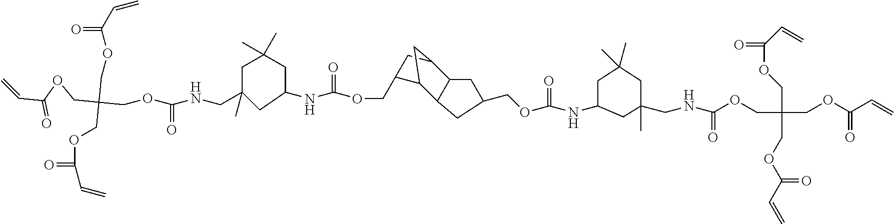 [SMILES: C=CC(=O)OCC(COC(=O)C=C)(COC(=O)C=C)COC(=O)NCC1(C)CC(NC(=O)OCC2CC3C4CC(COC(=O)NC5CC(C)(C)CC(C)(CNC(=O)OCC(COC(=O)C=C)(COC(=O)C=C)COC(=O)C=C)C5)C(C4)C3C2)CC(C)(C)C1]

### First Step

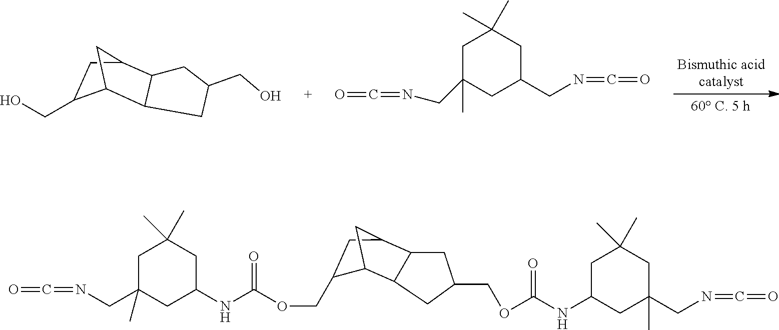 [SMILES: OCC1CC2C3CC(CO)C(C3)C2C1 ; CC1(C)CC(CN=C=O)CC(C)(CN=C=O)C1 ; CC1(C)CC(NC(=O)OCC2CC3C4CC(COC(=O)NC5CC(C)(C)CC(C)(CN=C=O)C5)C(C4)C3C2)CC(C)(CN=C=O)C1]

5 g of tricyclodecanedimethanol and 12 g of isophorone diisocyanate were dissolved in 10 g of methyl isobutyl ketone, and then 0.05 g of bismuthic acid catalyst was added and reacted under a nitrogen atmosphere at 60 degrees Celsius for 5 hours to obtain an isocyano-terminated prepolymer A1.

### Second Step

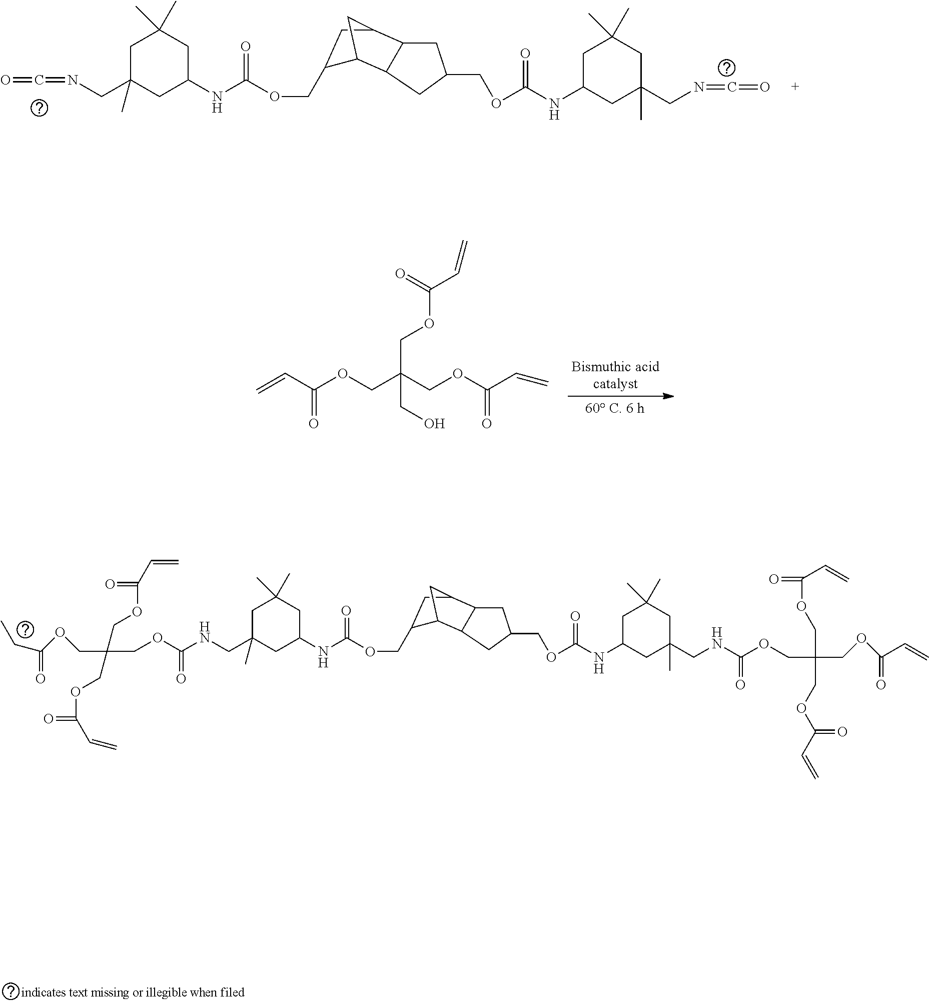 [SMILES: CC1(C)CC(NC(=O)OCC2CC3C4CC(COC(=O)NC5CC(C)(C)CC(C)(CN=C=O)C5)C(C4)C3C2)CC(C)(CN=C=O)C1 ; C=CC(=O)OCC(CO)(COC(=O)C=C)COC(=O)C=C ; C=CC(=O)OCC(COC(=O)C=C)(COC(=O)C=C)COC(=O)NCC1(C)CC(NC(=O)OCC2CC3C4CC(COC(=O)NC5CC(C)(C)CC(C)(CNC(=O)OCC(COC(=O)C=C)(COC(=O)C=C)COC(=O)CC)C5)C(C4)C3C2)CC(C)(C)C1]

15 g of pentaerythritol triacrylate and 27 g of the prepolymer A1 obtained in the first step were dissolved in 10 g of butyl acetate, and then 0.1 g of bismuthic acid catalyst was added and reacted under a nitrogen atmosphere at 60 degrees Celsius for 6 hours to obtain the hexa-functional polyurethane acrylate oligomer P1.

### Example 1: Preparation of Optical Assembly B1

Surface treatment of the organic substrate: a surface of the organic substrate PMMA was applied with the surface treatment composition for the organic substrate by roll-coating, and treated for 60 to 100 seconds. Then, the solvent was removed through an oven at 60 to 120 degrees Celsius to form a surface having a rough structure with a specific morphology.

Preparation of the coating: the surface having the rough structure with the specific morphology of the organic substrate PMMA was applied with a coating composition by roll-coating. Then, the solvent was removed through an oven at 60 to 120 degrees Celsius. The coating composition was cured by UV light in an energy of 100 to 1,000 mJ/cm² to obtain the coating having a thickness of 3 to 6 microns.

### Examples 2-4: Preparation of Optical Assemblies B2 to B4

The optical assemblies B2 to B4 can be prepared by the same method as that in Example 1, except that the specific components and the proportions in the surface treatment composition for the organic substrates and the coatings are different. The details are shown in Tables 1 and 2 below.

TABLE 1
Specific components of surface treatment composition for the
organic substrates used for optical assemblies B1 to B4

| | Components of surface treatment composition for the organic substrates | | |
|---|---|---|---|
| Examples | First solvent | Second solvent | Acrylic monomer |
| Example 1 | dimethyl sulfoxide | propanol | methyl methacrylate |
| | (5 parts by weight) | (85 parts by weight) | (15 parts by weight) |
| Example 2 | methyl acetamide | tetrahydrofuran | tetrahydrofurfuryl acrylate |
| | (8 parts by weight) | (82 parts by weight) | (10 parts by weight) |
| Example 3 | 2-pyrrolidone | ethyl acetate | butyl acrylate |
| | (10 parts by weight) | (70 parts by weight) | (20 parts by weight) |
| Example 4 | N,N-dimethylformamide | methyl ethyl ketone | isobutyl methacrylate |
| | (6 parts by weight) | (75 parts by weight) | (9 parts by weight) |

TABLE 2
Specific components of coatings used for optical assemblies B1 to B4

| | Components of coatings | | | |
|---|---|---|---|---|
| | Hexa- | | | |
| | functional | Acrylate monomer | | |
| | polyurethane | having a functionality | | |
| | acrylate | greater than or | | |
| Examples | oligomer P1 | equal to three | Photoinitiator | Solvent |
| Example | 60 parts by | trimethylol ethane | 1-hydroxycyclohexyl- | butyl acetate |
| 1 | weight | triacrylate | phenyl ketone | (195 parts by |
| | | (40 parts by weight) | (5 parts by weight) | weight) |
| Example | 70 parts by | pentaerythritol | 2-hydroxy-2-methyl-1- | methyl ethyl |
| 2 | weight | triacrylate | phenylpropan-1-one | ketone |
| | | (30 parts by weight) | (4 parts by weight) | (100 parts by |
| | | | | weight) |
| Example | 80 parts by | pentaerythritol | 2-hydroxy-2-methyl-1- | isopropanol |
| 3 | weight | tetramethacrylate | phenylpropan-1-one | (320 parts by |
| | | (20 parts by weight) | (4 parts by weight) | weight) |
| Example | 90 parts by | di(trimethylol- | 2-hydroxy-2-methyl-1- | methyl isobutyl |
| 4 | weight | propane)tetraacrylate | phenylpropan-1-one | ketone |
| | | (10 parts by weight) | (7 parts by weight) | (280 parts by |
| | | | | weight) |

### Performance Evaluation of Optical Assemblies

Transmittance performance: the luminous transmittance was evaluated according to the Chinese standard GB/T 2410.

Adhesion performance: a cross cut method was used to test. Specifically, the coating of each optical assembly was cut into 10×10 grids each having a size of 1 mm×1 mm by a cutting blade. After removal of the debris, the grids to be tested were firmly adhered with a 3M adhesive tape, and then the tape was quickly pulled off in a vertical direction. The detachment of the coatings was observed.

### Adhesion Determination Criteria:

5B, edges of the cuts are smooth, and no coating is detached at the edges and the intersections of the cuts.
4B, small flakes of the coating are detached at the intersections of the cuts, with the total detached area of less than 5%.
3B, small flakes of the coating are detached at the edges and the intersections of the cuts, with the total detached area of 5% to 15%.
2B, big flakes of the coating are detached at the edges and the intersections of the cuts, with the total detached area of 15% to 35%.
1B, big flakes of the coating are detached at the edges and the intersections of the cuts, with the total detached area of 35% to 65%.
0B, the detached region exceeds the standard of 1B.

Hardness performance by pencil: the coating surface of each optical assembly was scribed using Mitsubishi pencils with a hardness of H to 9H under a load of 750 g, observing the coating with or without scratches. The hardest pencil that failed to scratch the coating of the optical assembly was determined.

Friction resistance performance: the coating surface of each optical assembly was subjected to reciprocating friction using steel wool (000 #) under a load of 500 g, and the number of friction cycles at the occurrence of scratches was recorded.

TABLE 3
Surface roughness of surface-treated organic
substrates in optical assemblies B1 to B4

| Examples | Rq (nm) | Rz (nm) |
|---|---|---|
| Example 1 | 380 | 820 |
| Example 2 | 270 | 490 |
| Example 3 | 150 | 380 |
| Example 4 | 560 | 1200 |

TABLE 4
Performance evaluation of optical assemblies B1 to B4

| | Transmittance | Pencil | Friction | |
|---|---|---|---|---|
| Examples | (%) | Hardness | Resistance | Adhesion |
| Example 1 | 91.8 | 3 H | 20 | 5 B |
| Example 2 | 92.3 | 4 H | 30 | 5 B |
| Example 3 | 92.2 | 4 H | 35 | 5 B |
| Example 4 | 92.5 | 5 H | 50 | 5 B |

As can be seen from Table 3, the surfaces, which are obtained by surface-treating the organic substrate PMMA using the surface treatment composition for the organic substrate according to the embodiments of the present disclosure, have a rough structure with a specific morphology, thereby improving adhesion of the subsequently formed coatings to the organic substrate PMMA. Further, as can be seen from Table 4, the coatings of the optical assemblies B1 to B4 according to the embodiments of the present disclosure have an adhesion level of 5B in the cross cut test of the organic substrate PMMA, indicating that the coatings have excellent adhesion to the surface of the organic substrate PMMA treated by the surface treatment composition for the organic substrate according to the embodiments of the present disclosure, without visible coatings falling off.

Still referring to Table 4, for the optical assemblies B1 to B4 in the embodiments of the present disclosure, the coatings have a transmittance≥90%, a hardness by pencil (750 g)≥3H, and friction resistance (500 g)≥20 cycles, illustrating that the coatings can impart excellent hardness and wear resistance to the optical assemblies and maintain excellent optical performance to the optical assemblies.

According to the embodiments of the present disclosure, the first solvent and the acrylic monomer in the surface treatment composition for the organic substrate erode a surface of the organic substrate to form a rough structure. The second solvent regulates the morphology of the rough structure. On the one hand, the second solvent can balance the degree of erosion caused by the first solvent and the acrylic monomer on the surface of the organic substrate. On the other hand, the second solvent has a relatively low boiling point, which facilitates drying and rapid removal of the surface treatment composition for the organic substrate, thereby allowing the surface-treating process to be controlled. The surface treatment composition for the organic substrate according to the embodiments of the present disclosure enables the organic substrate to form the surface having a rough structure of a specific morphology, increasing a contact area of a subsequently formed coating. Moreover, a concave-convex fitting between the surface of the organic substrate and the coating forms a mechanical interlocking, thereby increasing adhesion of the coating to the organic substrate.

The detailed description of the surface treatment composition for the organic substrate, the method of surface-treating the organic substrate, the optical assembly, and the display panel are given in the embodiments of the present disclosure. The description of the above embodiments is merely intended to assist in understanding the method of the present disclosure and the core idea thereof, and should not be construed as limiting the scope of the present disclosure.

What is claimed is:

1. A surface treatment composition for an organic substrate comprising:
a first solvent having a dipole moment greater than or equal to 10×10⁻³⁰ C·m;
a second solvent having a dipole moment greater than 5×10⁻³⁰ and less than 10×10⁻³⁰ C·m and a boiling point of 50 to 150 degrees Celsius; and
an acrylic monomer.

2. The surface treatment composition for the organic substrate according to claim 1, wherein the first solvent comprises one or more of formamide, methylformamide, N,N-dimethylformamide, N,N-diethylformamide, acetamide, methylacetamide, N,N-dimethylacetamide, N-methylpropionamide, 2-pyrrolidone, N-methylpyrrolidone, F-caprolactam, dimethylsulfoxide, dimethylsulfone, or sulfolane.

3. The surface treatment composition for the organic substrate according to claim 1, wherein the second solvent comprises one or more of methanol, ethanol, propanol, isopropanol, butanol, isobutanol, tert-butanol, pentanol, 2-methyl-1-butanol, isopentanol, sec-pentanol, tert-pentanol, tetrahydrofuran, tetrahydropyran, 2-methyltetrahydrofuran, ethylene glycol dimethyl ether, ethylene glycol diethyl ether, acetal, ethyl formate, propyl formate, butyl formate, isobutyl formate, amyl formate, isoamyl formate, methyl acetate, ethyl acetate, propyl acetate, butyl acetate, isobutyl acetate, sec-butyl acetate, tert-butyl acetate, amyl acetate, isoamyl acetate, methyl isoamyl acetate, methyl propionate, ethyl propionate, propyl propionate, butyl propionate, methyl butyrate, ethyl butyrate, propyl butyrate, isopropyl butyrate, methyl isobutyrate, ethyl isobutyrate, acetone, butanone, 2-pentanone, 3-pentanone, 3-methyl-2-butanone, 2-hexanone, 3-hexanone, 2-methyl-3-pentanone, 4-methyl-2-pentanone, 2,4-dimethyl-3-pentanone, cyclopentanone, or cyclohexanone.

4. The surface treatment composition for the organic substrate according to claim 1, wherein the acrylic monomer comprises one or more of acrylic acid, methyl acrylate, ethyl acrylate, butyl acrylate, isobutyl acrylate, methyl methacrylate, ethyl methacrylate, butyl methacrylate, isobutyl methacrylate, hydroxyethyl acrylate, tetrahydrofurfuryl acrylate, lauryl acrylate, isooctyl acrylate, or hydroxyl acrylate.

5. The surface treatment composition for the organic substrate according to claim 1, wherein the surface treatment composition for an organic substrate comprises 1 to 10 parts by weight of the first solvent, 65 to 94 parts by weight of the second solvent, and 5 to 25 parts by weight of the acrylic monomer.

6. An optical assembly comprising:
an organic substrate having a surface treated by a surface treatment composition for the organic substrate, wherein the surface has a root mean square surface roughness of 10 to 1,000 nm and a maximum height surface roughness of 20 to 2,000 nm.

7. The optical assembly according to claim 6, further comprising a coating disposed on the surface.

8. The optical assembly according to claim 7, wherein the coating comprises a polyurethane acrylate oligomer having a functionality greater than or equal to six.

9. The optical assembly of claim 8, wherein the coating comprises a hexa-functional polyurethane acrylate oligomer having a structure as follows: ▮

10. The optical assembly according to claim 8, wherein the coating further comprises an acrylate monomer having a functionality greater than or equal to three and a photoinitiator.

11. The optical assembly according to claim 10, wherein the acrylate monomer having the functionality greater than or equal to three comprises one or more of trimethylolethane tri(meth)acrylate, trimethylolpropane tri(meth)acrylate, glycerol tri(meth)acrylate, pentaerythritol tri(meth)acrylate, di(trimethylolpropane) tri(meth)acrylate, dipentaerythritol tri(meth)acrylate, pentaerythritol tetra(meth)acrylate, di(trimethylolpropane) tetra(meth)acrylate, dipentaerythritol tetra(meth)acrylate, dipentaerythritol penta(meth)acrylate, di(trimethylolpropane) penta(meth)acrylate, dipentaerythritol hexa(meth)acrylate, or di(trimethylolpropane) hexa(meth)acrylate.

12. The optical assembly according to claim 10, wherein the photoinitiator comprises one or more of 4-phenoxydichloroacetophenone, 4-tert-butyldichloroacetophenone, 4-tert-butyltrichloroacetophenone, diethoxyacetophenone, 2-hydroxy-2-methyl-1-phenylpropan-1-one, 1-(4-isopropylphenyl)-2-hydroxy-2-methylpropan-1-one, 1-(4-dodecylphenyl)-2-hydroxy-2-methylpropan-1-one, 4-(2-hydroxyethoxy)-phenyl(2-hydroxy-2-propyl) ketone, 1-hydroxycyclohexylphenyl ketone, benzoin, benzoin methyl ether, benzoin ethyl ether, benzyl dimethyl ketal, acylphosphine oxides, itanocene compounds, benzophenone, benzoylbenzoic acid, benzoylbenzoic acid methyl ether, 4-phenylbenzophenone, hydroxybenzophenone, 4-benzoyl-4′-methyldiphenyl sulfide, 3,3′-dimethyl-4-methoxybenzophenone, thioxanthone, 2-chlorothioxanthone, 2-methylthioxanthone, 2,4-dimethylthioxanthone, or isopropylthioxanthone.

13. The optical assembly according to claim 10, wherein the coating comprises 60 to 100 parts by weight of the polyurethane acrylate oligomer having the functionality greater than or equal to six;
0 to 40 parts by weight of the acrylate monomer having the functionality greater than or equal to three; and
1 to 10 parts by weight of the photoinitiator.

14. A display panel, comprising:
a panel body, and
a optical assembly, the optical assembly being provided on a surface of the panel body,
wherein the optical assembly comprises:
an organic substrate close to the panel body, the organic substrate has a surface treated by a surface treatment composition for the organic substrate, the surface is on a side of the organic substrate away from the panel body, and the surface has a root mean square surface roughness of 10 to 1,000 nm and a maximum height surface roughness of 20 to 2,000 nm.

15. The display panel according to claim 14, wherein the optical assembly further comprises a coating disposed on the surface.

16. The display panel according to claim 15, wherein the coating comprises a polyurethane acrylate oligomer having a functionality greater than or equal to six.

17. The display panel of claim 16, wherein the coating comprises a hexa-functional polyurethane acrylate oligomer having a structure as follows: ▮

18. The display panel according to claim 16, wherein the coating further comprises an acrylate monomer having a functionality greater than or equal to three and a photoinitiator.

19. The display panel according to claim 18, wherein the coating comprises 60 to 100 parts by weight of the polyurethane acrylate oligomer having the functionality greater than or equal to six;
0 to 40 parts by weight of the acrylate monomer having the functionality greater than or equal to three; and
1 to 10 parts by weight of the photoinitiator.
